(19) United States
(12) Patent Application Publication
(10) Pub. No.: US 2004/0007770 A1
(43) Pub. Date: Jan. 15, 2004

(54) Semiconductor-mounting substrate used to manufacture electronic packages, and production process for producing such semiconductor-mounting substrate

(76) Inventor: Kenichi Kurihara, Kanagawa (JP)

Correspondence Address: KATTEN MUCHIN ZAVIS ROSENMAN, 575 MADISON AVENUE, NEW YORK, NY, 10022-2585, US

(21) Appl. No.: 10/457,887

(22) Filed: Jun. 10, 2003

(30) Foreign Application Priority Data
Jul. 9, 2002 (JP) 2002-199608

(51) Int. Cl. H01L 23/02

(52) U.S. Cl. 257/685

(57) ABSTRACT

In a semiconductor-mounting substrate used to manufacture a plurality of electronic packages, a first multi-layer substrate section is composed of a metal film layer and an electronic insulation layer, and a plurality of package areas are defined on a surface of the first substrate section. A second multi-layer substrate section is composed of at least two metal film layers which are spaced from an electric insulation layer intervened therebetween. The first substrate section is laminated onto the second substrate section, using a press machine, such that the electronic insulation layer of the first substrate section is laid on one of the metal film layers of the second substrate section. A chip-mounting opening is formed at each package area in the first substrate section prior to the lamination of the first substrate section onto the second substrate section.

### BACKGROUND OF THE INVENTION

1. Field of the Invention

The present invention relates to a semiconductor-mounting substrate which is used to manufacture a plurality of electronic packages, and also relates to a production process for producing such a semiconductor-mounting substrate.

2. Description of the Related Art

In general, a semiconductor-mounting substrate has been considerably large in size in comparison with the size of an individual electronic package to be manufactured, in order to simultaneously manufacture a plurality of electronic packages, such as BGA (ball grid array) packages or the like.

Usually, a semiconductor-mounting substrate is produced from a multi-layer substrate composed of three metal film layers and two electronic insulation layers, which are alternately laminated. Namely, two metal film layers form two outermost metal film layers of the multi-layer substrate, and the remaining metal film layer forms an intermediate metal film layer of the multi-layer substrate, with the two electric insulation layers being intervened between the outermost metal film layers and the intermediate metal film layer.

The outermost metal film layers are defined as the uppermost and lowermost metal film layers of the multi-layer substrate, and a plurality of rectangular package areas are previously defined on the surface of the uppermost metal film layer. The uppermost and lowermost metal film layers are patterned by a photolithography process and an etching process. Namely, a wiring pattern is formed at each package area on the uppermost metal film layer, and a plurality of electrode pads are correspondingly formed in the lowermost metal film layer. Also, through holes and via structures are suitably formed in the multi-layer substrate at each package area, to thereby establish electrical connections between each wiring pattern and the corresponding electrode pads.

Thereafter, rectangular openings are formed one by one in the multi-layer substrate at each package area, using a router machine, such that the intermediate metal film sheet is exposed to the outside, resulting in the production of the semiconductor-mounting substrate from the multi-layer substrate. This semiconductor-mounting substrate is commercially distributed and circulated as a component part for manufacturing electronic packages, such as BGA packages or the like.

For example, in order to manufacture BGA packages, a semiconductor chip is mounted on each area of the intermediate metal film layer, which is exposed by the corresponding rectangular opening, and then electrical connections are established between the semiconductor chip and the corresponding wiring pattern by bonding-wires, using a wire bonding machine. Subsequently, each of the semiconductor chips is sealed together with the bonding-wires by a molded resin, and metal balls are adhered to the electrode pads formed in the lowermost metal film layer. Thus, a BGA package is produced at each package area on the semiconductor-mounting substrate, and the semiconductor-mounting substrate is cut and separated into a plurality of BGA packages.

In each BGA package, the intermediate metal layer functions as a heat-radiating layer for the mounted semiconductor chip, as disclosed in Japanese Laid-Open Patent Publication (KOKAI) No. HEI-11-307681.

The above-mentioned production process for the semiconductor-mounting substrate is very inefficient, because the rectangular openings must be formed one by one in the multi-layer substrate, using the router machine, resulting in an increase in the production cost for the semiconductor-mounting substrates. Also, as a thickness of the intermediate metal film layer becomes thinner, it is more difficult to form the rectangular openings in the multi-layer substrate, because the router machine must be strictly and accurately controlled such that the thin metal film layer cannot be pierced by a tool of the router machine. Thus, the thinner the thickness of the intermediate metal film layer, the higher the production cost for the semiconductor-mounting substrates.

### SUMMARY OF THE INVENTION

Therefore, a main object of the present invention is to provide a production process for producing a semiconductor-mounting substrate, in which the production of the semiconductor-mounting substrate can be efficiently carried out at low cost.

Another object of the present invention is to provide a semiconductor-mounting substrate produced by the above-mentioned production process.

In accordance with a first aspect of the present invention, there is provided a semiconductor-mounting substrate used to manufacture a plurality of electronic packages. The semiconductor-mounting substrate comprises a first multi-layer substrate section composed of a metal film layer and an electronic insulation layer, and a plurality of package areas are defined on a surface of the first multi-layer substrate section. The semiconductor-mounting substrate also comprises a second multi-layer substrate section composed of at least two metal film layers which are spaced from an electric insulation layer intervened therebetween. The first multi-layer substrate section is laminated onto the second multi-layer substrate section, using a press machine, such that the electronic insulation layer of the first multi-layer substrate section is laid on one of the metal film layers of the second multi-layer substrate section. A chip-mounting opening is formed at each package area in the first multi-layer substrate section prior to the lamination of the first multi-layer substrate section onto the second multi-layer substrate section.

The metal film layer of the first multi-layer substrate section may be defined as an uppermost metal film layer of the semiconductor-mounting substrate, and the other metal film layer of the second multi-layer substrate section may be defined as a lowermost metal film layer of the semiconductor-mounting substrate.

The uppermost and lowermost metal film layers of the semiconductor-mounting substrate may be patterned such that a wiring pattern is formed at each package area in the uppermost metal layer, and such that a plurality of electrode pads are correspondingly formed in the lowermost metal film layer.

Also, the respective outermost surfaces of the semiconductor-mounting substrate may be coated with a protective material such that protective layers are formed thereon. Further, the respective protective layers of the semiconductor-mounting substrate may be patterned such that partial areas of the protective layers are left as protective or solder-resist coating areas on the respective surfaces of the semiconductor-mounting substrate.

Preferably, at least one stress-relieving opening is formed at each package area in the first multi-layer substrate section in the vicinity of the corresponding chip-mounting opening. Optionally, at least one stress-relieving opening may be formed at each package area in the metal film layer of the first multi-layer substrate section in the vicinity of the corresponding chip-mounting opening.

In accordance with a second aspect of the present invention, there is provided a production process for producing a semiconductor-mounting substrate used to manufacture a plurality of electronic packages, which process comprises: preparing a first multi-layer substrate section composed of a metal film layer and an electronic insulation layer, a plurality of package areas being defined on a surface of the first multi-layer substrate section; forming a chip-mounting opening at each package area in the first multi-layer substrate section; preparing a second multi-layer substrate section composed of at least two metal film layers which are spaced from an electric insulation layer intervened therebetween; and laminating the first multi-layer substrate section onto the second multi-layer substrate section, using a press machine, such that the electronic insulation layer of the first multi-layer substrate section is laid on one of the metal film layers of the second multi-layer substrate section, resulting in production of the semiconductor-mounting substrate.

In the second aspect of the present invention, the formation of the chip-mounting openings in the first multi-layer substrate section may be carried out using a punching machine. Preferably, the formation of the chip-mounting openings in a stack of first multi-layer substrate sections is carried out at once using a punching machine.

In the second aspect of the present invention, the production process may further comprise forming at least one stress-relieving opening at each package area in the first multi-layer substrate section in the vicinity of the corresponding chip-mounting opening. The formation of the stress-relieving openings in the first multi-layer substrate section may be carried out, using a punching machine. Preferably, the formation of the stress-relieving openings in a stack of first multi-layer substrate sections is carried out at once using a punching machine.

In accordance with a third aspect of the present invention, there is provided a production process for producing a semiconductor-mounting substrate used to manufacture a plurality of electronic packages, which process comprises: preparing a metal film, a plurality of package areas being defined on a surface of the metal film; forming at least one stress-relieving opening at each package area in the metal film; laminating the metal film onto an electric insulation sheet to thereby produce a first multi-layer substrate section composed of a metal film layer and an electronic insulation layer derived from the metal film and the electric insulation sheet, respectively; forming a chip-mounting opening at each package area in the first multi-layer substrate section in the vicinity of the corresponding stress-relieving opening; preparing a second multi-layer substrate section composed of at least two metal film layers which are spaced from an electric insulation layer intervened therebetween; and laminating the first multi-layer substrate section onto the second multi-layer substrate section, using a press machine, such that the electronic insulation layer of the first multi-layer substrate section is laid on one of the metal film layers of the second multi-layer substrate section, resulting in a production of the semiconductor-mounting substrate.

In the third aspect of the present invention, the formation of the stress-relieving openings in the metal film may be carried out, using a punching machine. Preferably, the formation of the stress-relieving openings in a stack of metal films is carried out at once using a punching machine.

Also, in the third aspect of the present invention, the formation of the chip-mounting openings in the first multi-layer substrate section may be carried out using a punching machine. Preferably, the formation of the chip-mounting openings in a stack of first multi-layer substrate sections is carried out at once using a punching machine.

In the second and third aspects of the present invention, the metal film layer of the first multi-layer substrate section may be defined as an uppermost metal film layer of the semiconductor-mounting substrate, and the other metal film layer of the second multi-layer substrate section may be defined as a lowermost metal film layer of the semiconductor-mounting substrate.

In this case, the production process may comprises patterning the uppermost and lowermost metal film layers of the semiconductor-mounting substrate such that a wiring pattern is formed at each package area in the uppermost metal layer, and such that a plurality of electrode pads are correspondingly formed in the lowermost metal film layer. Also, the production process may further comprise coating the respective outermost surfaces of the semiconductor-mounting substrate with a protective material to form protective layers thereon. In addition, the production process may further comprise patterning the respective protective layers of the semiconductor-mounting substrate such that partial areas of the protective layers are left as protective or solder-resist coating areas on the respective surfaces of the semiconductor-mounting substrate.

In the first, second and third aspects of the present invention, each of the chip-mounting openings may be formed as a rectangular opening. Optionally, each of the openings may be formed as a generally star-shaped opening. In this case, each of inner side wall faces defining the generally star-shaped opening is convexly curved.

Also, in the first, second and third aspects of the present invention, each of the stress-relieving openings may be formed as a slot-shaped opening. Optionally, each of the stress-relieving openings may be formed as a generally crescent-shaped opening. In this case, at least one of side wall faces defining the generally crescent-shaped opening is concavely curved.

### BRIEF DESCRIPTION OF THE DRAWINGS

The above objects and other objects will be more clearly understood from the description set forth below, with reference to the accompanying drawings, wherein:

FIG. 1 is a perspective view of a first embodiment of a semiconductor-mounting substrate according to the present invention;

FIG. 2A is a partial cross-sectional view of a first multi-layer substrate section forming a part of the semiconductor-mounting substrate shown in FIG. 1, showing a first representative step of a first embodiment of a production process for producing the semiconductor-mounting substrate of FIG. 1, according to the present invention;

FIG. 2B is a partial cross-sectional view, similar to FIG. 2A, showing a second representative step of the first embodiment of the production process according to the present invention;

FIG. 2C is a partial cross-sectional view of a second multi-layer substrate section forming another part of the semiconductor-mounting substrate shown in FIG. 1, showing a third representative step of the first embodiment of the production process according to the present invention;

FIG. 2D is a partial cross-sectional view of the semiconductor-mounting substrate composed of the first and second multi-layer substrate sections, corresponding to a cross section taken along the II-II line of FIG. 1, showing a fourth representative step of the first embodiment of the production process according to the present invention;

FIG. 2E is a partial cross-sectional view of the semiconductor-mounting substrate, outermost and lowermost metal film layers of which are patterned, showing a fifth representative step of the first embodiment of the production process according to the present invention;

FIG. 2F is a partial cross-sectional view of the semiconductor-mounting substrate, the upper and lower surfaces of which are coated with a solder resist material to thereby form solder resist layers thereon, showing a sixth representative step of the first embodiment of the production process according to the present invention;

FIG. 2G is a partial cross-sectional view of the semiconductor-mounting substrate, the solder resist layers of which are patterned, showing a seventh representative step of the first embodiment of the production process according to the present invention;

FIG. 3A is a partial cross-sectional view of a multi-layer substrate, showing a first representative step of a conventional production process for producing a semiconductor-mounting substrate;

FIG. 3B is a partial cross-sectional view of the multi-layer substrate, the upper and lower surfaces of which are coated with a solder resist material to form solder resist layers thereon, showing a second representative step of the conventional production process;

FIG. 3C is a partial cross-sectional view of the multi-layer substrate, uppermost and lowermost metal film layers are patterned, showing a third representative step of the conventional production process;

FIG. 3D is a partial cross-sectional view of the multi-layer substrate, the solder resist layers of which are patterned, showing a fourth representative step of the conventional production process;

FIG. 3E is a partial cross-sectional view of a semiconductor-mounting substrate produced from the multi-layer substrate, showing a fifth representative step of the conventional production process;

FIG. 4 is a perspective view of a second embodiment of the semiconductor-mounting substrate according to the present invention;

FIG. 5 is a plan view of the second embodiment of the semiconductor-mounting substrate shown in FIG. 4;

FIG. 6A is a partial cross-sectional view of a first multi-layer substrate section forming a part of the semiconductor-mounting substrate shown in FIGS. 4 and 5, showing a first representative step of a first embodiment of a production process for producing the semiconductor-mounting substrate of FIGS. 4 and 5, according to the present invention;

FIG. 6B is a partial cross-sectional view, similar to FIG. 6A, showing a second representative step of the second embodiment of the production process according to the present invention;

FIG. 6C is a partial cross-sectional view, similar to FIG. 6B, showing a third representative step of the second embodiment of the production process according to the present invention;

FIG. 6D is a partial cross-sectional view of a second multi-layer substrate section forming another part of the semiconductor-mounting substrate shown in FIGS. 4 and 5, showing a fourth representative step of the second embodiment of the production process according to the present invention;

FIG. 6E is a partial cross-sectional view of the semiconductor-mounting substrate composed of the first and second multi-layer substrate sections, corresponding to a cross section taken along the VI-VI line of FIG. 5, showing a fifth representative step of the second embodiment of the production process according to the present invention;

FIG. 6F is a partial cross-sectional view of the semiconductor-mounting substrate, outermost and lowermost metal film layers of which are patterned, showing a sixth representative step of the second embodiment of the production process according to the present invention;

FIG. 6G is a partial cross-sectional view of the semiconductor-mounting substrate, the upper and lower surfaces of which are coated with a solder resist material to thereby form solder resist layers thereon, showing a seventh representative step of the second embodiment of the production process according to the present invention;

FIG. 6H is a partial cross-sectional view of the semiconductor-mounting substrate, the solder resist layers of which are patterned, showing an eighth representative step of the second embodiment of the production process according to the present invention;

FIG. 7 is a perspective view of a third embodiment of the semiconductor-mounting substrate according to the present invention;

FIG. 8 is a plan view of the third embodiment of the semiconductor-mounting substrate shown in FIG. 7;

FIG. 9A is a partial cross-sectional view of a metal film sheet forming a part of the semiconductor-mounting substrate shown in FIGS. 7 and 8, showing a first representative step of a third embodiment of a production process for producing the semiconductor-mounting substrate of FIGS. 7 and 8, according to the present invention;

FIG. 9B is a partial cross-sectional view, similar to FIG. 9A, showing a second representative step of the third embodiment of the production process according to the present invention;

FIG. 9C is a partial cross-sectional view of a first multi-layer substrate section forming another part of the semiconductor-mounting substrate shown in FIGS. 7 and 8, showing a third representative step of the third embodiment of the production process according to the present invention;

FIG. 9D is a partial cross-sectional view, similar to FIG. 9C, showing a fourth representative step of the third embodiment of the production process according to the present invention;

FIG. 9E is a partial cross-sectional view of a second multi-layer substrate section forming yet another part of the semiconductor-mounting substrate shown in FIGS. 7 and 8, showing a fifth representative step of the third embodiment of the production process according to the present invention;

FIG. 9F is a partial cross-sectional view of the semiconductor-mounting substrate composed of the first and second multi-layer substrate sections, corresponding to a cross section taken along the IX-IX line of FIG. 8, showing a sixth representative step of the third embodiment of the production process according to the present invention;

FIG. 9G is a partial cross-sectional view of the semiconductor-mounting substrate, outermost and lowermost metal film layers of which are patterned, showing a seventh representative step of the third embodiment of the production process according to the present invention;

FIG. 9H is a partial cross-sectional view of the semiconductor-mounting substrate, the upper and lower surfaces of which are coated with a solder resist material to thereby form solder resist layers thereon, showing a eighth representative step of the third embodiment of the production process according to the present invention;

FIG. 9I is a partial cross-sectional view of the semiconductor-mounting substrate, the solder resist layers of which are patterned, showing a ninth representative step of the third embodiment of the production process according to the present invention;

FIG. 10 is a partial plan view showing a first modification of the semiconductor-mounting substrate according to the present invention;

FIG. 11 is a partial plan view showing a second modification of the semiconductor-mounting substrate according to the present invention;

FIG. 12 is a partial plan view showing a third modification of the semiconductor-mounting substrate according to the present invention; and

FIG. 13 is a partial plan view showing a fourth modification of the semiconductor-mounting substrate according to the present invention.

### DESCRIPTION OF THE PREFERRED EMBODIMENTS

First Embodiment

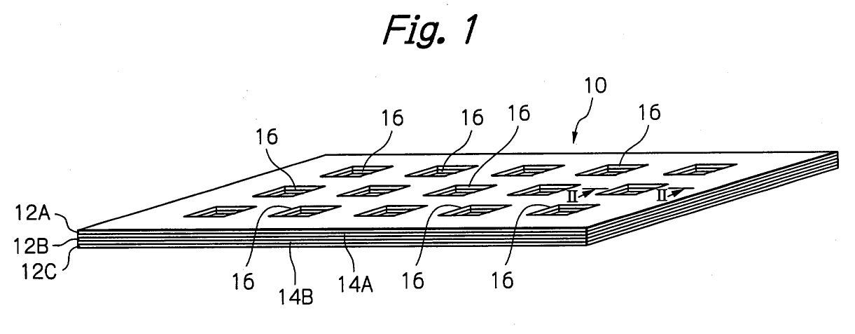

With reference to FIG. 1, a first embodiment of a semiconductor-mounting substrate according to the present invention is illustrated in a perspective view, and is used to manufacture a plurality of electronic packages, such as BGA (ball grid array) packages.

As shown in FIG. 1, the semiconductor-mounting substrate, generally indicated by reference 10, is formed as a multi-layer substrate. In this first embodiment, the semiconductor-mounting substrate or multi-layer substrate 10 includes three metal film layers 12A, 12B, and 12C, and two electric insulation layers 14A and 14B, which are alternately laminated. Namely, the metal film layers 12A and 12C form the outermost layers of the multi-layer substrate 10, and the metal film layer 12B forms an intermediate layer, with the respective electric insulation layers 14A and 14B being intervened between the outermost metal film layer 12A and the intermediate metal film layer 12B and between the intermediate metal film layer 12B and the outermost metal film layer 12C.

Note, for the sake of explanatory convenience, the respective outermost metal film layers 12A and 12C are referred to as the uppermost metal film layer and the lowermost metal film layer hereinafter.

A plurality of rectangular package areas are defined on the surface of the uppermost metal film layer 12A, and a rectangular recess or opening 16 is formed at each package area in both the uppermost metal film layer 12A and the electric insulation layer 14A, such that the intermediate metal film layer 12B is exposed to the outside at each rectangular opening 16. The respective exposed rectangular areas of the intermediate metal film layer 12B are used to mount semiconductor chips or bare chips (not shown). Namely, each of the rectangular openings 16 serves as a chip-mounting opening.

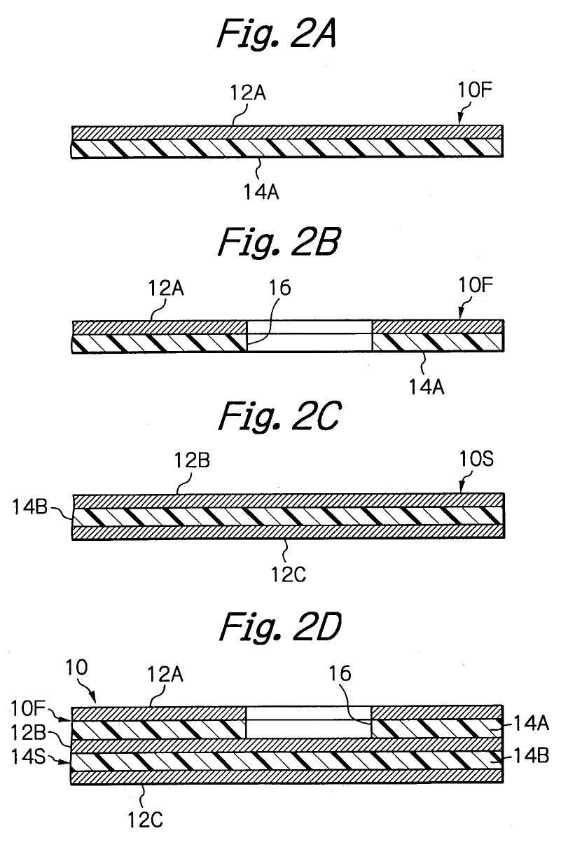

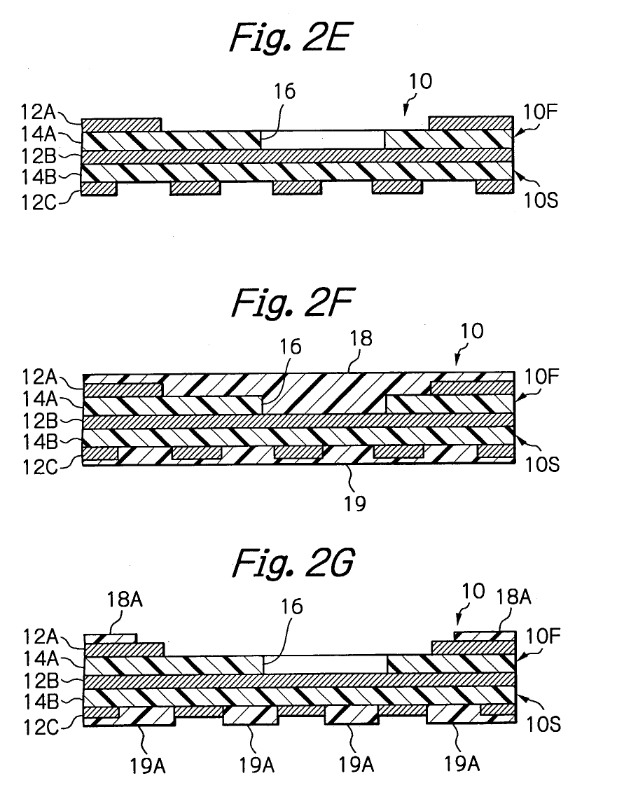

FIGS. 2A to 2D show representative steps forming a production process for producing the semiconductor-mounting substrate or multi-layer substrate 10 shown in FIG. 1.

First, as shown in FIG. 2A, a first multi-layer substrate section 10F is prepared, and is composed of the uppermost metal film layer 12A and the electric insulation layer 14A. In this first embodiment, the uppermost metal film layer 12A is made from a copper film, and the electric insulation layer 14A is made from a prepreg sheet composed of a glass fiber fabric impregnated with a suitable resin material, such as epoxy or the like. Namely, the copper film 12A is laid on the prepreg sheet 14A in which the contained epoxy is in a semi-cured state, and then both the copper film 12A and the prepreg sheet 14A are pressed against each other by a suitable press machine (not shown), resulting in the production of the first multi-layer substrate section 10F.

As shown in FIG. 2B, all the chip-mounting openings 16 are formed at the respective package areas in the first multi-layer substrate section 10F by a suitable punching press machine (not shown). Note, in FIG. 2B, only one chip-mounting opening 16 is representatively illustrated. It is possible to efficiently carry out the formation of the chip-mounting openings 16 at once in a stack of first multi-layer substrate sections 10F, using the punching press machine. Namely, it is possible to achieve the formation processing of the chip-mounting openings 16 at low cost.

As shown in FIG. 2C, a second multi-layer substrate section 10S is prepared, and is composed of the intermediate and lowermost metal film layers 12B and 12C, and the electric insulation layer 14B. Also, each of the metal film layers 12B and 12C may be made from a copper film, and the electric insulation layer 14B may be made from a prepreg sheet composed of a glass fiber fabric impregnated with epoxy. Namely, the prepreg sheet 14B, in which the contained epoxy is in a semi-cured state, is sandwiched between the copper films 12B and 12C, and then these elements 12B, 12C, and 24B are pressed against each other by a suitable press machine (not shown), resulting in the production of the second multi-layer substrate section 10S.

Thereafter, the first multi-layer substrate section 10F is laminated onto the second multi-layer substrate section 10S such that the electric insulation layer 14A of the first multi-layer substrate section 10F is laid on the intermediate metal film layer 12B of the second multi-layer substrate section 10S. Then, the laminated first and second multi-layer substrate sections 10F and 10S are pressed against each other by a suitable press machine (not shown), resulting in the production of the semiconductor-mounting substrate 10, as shown in FIG. 2D. Although the first and second multi-layer substrate sections 10F and 10S can be securely adhered to each other, due to the epoxy contained in the prepreg sheet 14A being in the semi-cured state, a suitable adhesive agent may be applied to the surface of the electric insulation layer 14A of the first multi-layer substrate section 10F, if necessary. Note, FIG. 2D corresponds to a partial cross-sectional view of the semiconductor-mounting substrate 10, taken along the II-II line of FIG. 1.

As stated above, although the semiconductor chips are mounted on respective areas of the intermediate metal film layer 12B, which are exposed by the chip-mounting openings 16, the semiconductor-mounting substrate 10 must be further processed before the mounting of the semiconductor chips can be performed, as shown in FIG. 2E, 2F, and 2G.

In particular, as shown in FIG. 2E, the uppermost and lowermost metal film layers 12A and 12C are patterned by a photolithography process and an etching process. Namely, a wiring pattern is formed at each package area in the uppermost metal film layer 12A, and a plurality of electrode pads are correspondingly formed in the lowermost metal film layer 12C. Also, although not illustrated, through holes and via structures are suitably formed in the semiconductor-mounting substrate 10 at each package area, to thereby establish electrical connections between each wiring pattern and the corresponding electrode pads.

Subsequently, as shown in FIG. 2F, the respective upper and lower surfaces of the semiconductor-mounting substrate 10 are coated with a protective or solder resist material to thereby form solder resist layers 18 and 19 thereon. Namely, the wiring patterns formed in the uppermost metal film layer 12A are covered with the solder resist layer 18, and the electrode pads formed in the lowermost metal film layer 12C are covered with the solder resist layer 19. Note, the solder resist material may be composed of epoxy.

Then, as shown in FIG. 2G, the solder resist layers 18 and 19 are patterned by a photolithography process and an etching process. Namely, partial areas of the solder resist layer 18 are left as protective or solder-resist coating areas 18A on each wiring pattern such that electrode pads included in each wiring pattern are exposed to the outside, and partial areas of the solder resist layer 19 are left as protective or solder-resist coating areas 19A on the electrical insulation layer 14B such that the electrode pads formed in the lowermost metal film layer 12C are exposed to the outside.

Thereafter, a semiconductor chip is mounted on each area of the intermediate metal film layer 12B which is exposed by the corresponding opening 16, and then electrical connections are established between the semiconductor chip and the exposed electrode pads of the corresponding wiring pattern by bonding-wires, using a wire bonding machine (not shown). Then, each of the semiconductor chips is sealed together with the bonding-wires by a molded resin, and metal balls are adhered to the electrode pads formed in the lowermost metal film layer 12C. Thus, a BGA package is produced at each packages area on the semiconductor-mounting substrate 10, and the semiconductor-mounting substrate 10 is cut and separated into the plurality of BGA packages.

Note, in this field, the semiconductor-mounting substrate 10 per se, as obtained in steps shown in FIG. 2D, 2E, 2F or 2G, may be commercially distributed and circulated as a component part for manufacturing electronic packages, such as BGA packages or the like.

Prior Art

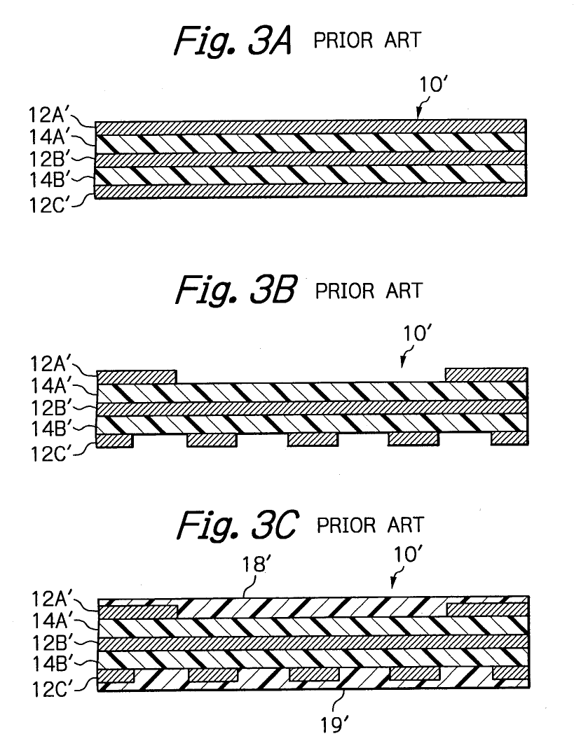

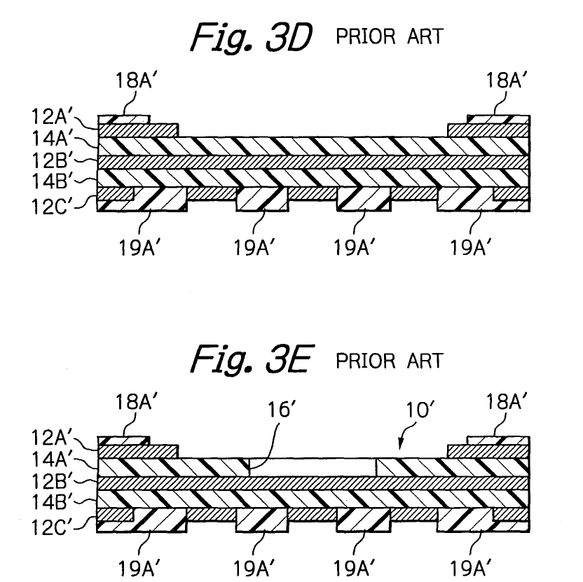

For better understanding of the present invention, with reference to FIGS. 3A, 3B, 3C, and 3D, a conventional production process for producing a semiconductor-mounting substrate is explained below.

First, as shown in FIG. 3A, a multi-layer substrate 10′ is prepared, and is composed of three metal film layers 12A′, 12B′, and 12C′, and two electric insulation layers 14A′ and 14B′, which are alternately laminated such that the respective metal film layers 12A′ and 12C′ form uppermost and lowermost layers of the multi-layer substrate 10′. Each of the metal film layers 12A′, 12B′, and 12C′ is made from a copper film, and each of the electric insulation layers 14A′ and 14B′ is made from a prepreg sheet composed of a glass fiber fabric impregnated with a suitable resin material, such as epoxy or the like. Note, a plurality of rectangular package areas are previously defined on the surface of the uppermost metal film layer 12A′.

As shown in FIG. 3B, the uppermost and lowermost metal film layers 12A′ and 12C′ are patterned by a photolithography process and an etching process. Namely, a wiring pattern is formed at each package area in the uppermost metal film layer 12A′, and a plurality of electrode pads are correspondingly formed in the lowermost metal film layer 12C′. Also, although not illustrated, through holes and via structures are suitably formed in the multi-layer substrate 10′ at each package area, to thereby establish electrical connections between each wiring pattern and the corresponding electrode pads.

Then, as shown in FIG. 3C, the respective upper and lower surfaces of the multi-layer substrate 10′ are coated with a protective or solder resist material to thereby form solder resist layers 18′ and 19′ thereon. Namely, the wiring patterns formed in the uppermost metal film layer 12A′ are covered with the solder resist layer 18′, and the electrode pads formed in the lowermost metal film layer 12C′ are covered with the solder resist layer 19′. Note, the solder resist material may be composed of epoxy.

Subsequently, as shown in FIG. 3D, the solder resist layers 18′ and 19′ are patterned by a photolithography process and an etching process. Namely, partial areas of the solder resist layer 18′ are left as protective or solder resist coating areas 18A′ on each wiring pattern such that electrode pads included in each wiring pattern are exposed to the outside, and partial areas of the solder resist layer 19′ are left as protective or solder resist coating areas 19A′ on the electrical insulation layer 14B′ such that the electrode pads formed in the lowermost metal film layer 12C′ are exposed to the outside.

Finally, as shown in FIG. 3E, rectangular-shaped chip-mounting openings 16′ are formed one by one in the electric insulation layer 14A′ at each package area, using a router machine (not shown), resulting in a production of a semiconductor-mounting substrate from the multi-layer substrate 10′. Namely, by forming the chip-mounting openings 16′ in the electric insulation layer 14A′ at the package areas, the multi-layer substrate 10′ is produced as the semiconductor-mounting substrate.

Thereafter, a semiconductor chip is mounted on each area of the intermediate metal film layer 12B′, which is exposed by the corresponding opening 16′, and electrical connections are established between the semiconductor chip and the exposed electrode pads of the corresponding wiring pattern by bonding-wires, using a wire bonding machine (not shown). Then, each of the semiconductor chips is sealed together with the bonding-wires by a molded resin, and metal balls are adhered to the electrode pads formed in the lowermost metal film layer 12C′. Thus, a BGA package is produced at each package area on the semiconductor-mounting substrate 10′, and the semiconductor-mounting substrate 10′ is cut and separated into a plurality of BGA packages.

As is apparent from the comparison of the aforesaid conventional production process with the production process according to the present invention, the production of the semiconductor-mounting substrate 10 can be efficiently carried out at low cost, because the formation of the chip-mounting openings 16 can be carried out at once in the stack of first multi-layer substrate sections 10F, using the punching press machine. On the contrary, the conventional production process of the semiconductor-mounting substrate 10′ is very inefficient, because the chip-mounting openings 16′ must be formed one by one in the electric insulation layer 14A′, using the router machine, resulting in an increase in the production cost for the semiconductor-mounting substrates 10′.

Also, as the thickness of the metal film layer 12B′ becomes thinner, it is more difficult to form the chip-mounting openings 16′ in the electric insulation layer 14A′, because the router machine must be strictly and accurately controlled such that the thin metal film layer 12B′ cannot be pierced by a tool of the router machine. Thus, the thinner the thickness of the metal film layer 12B′, the higher the production cost for the semiconductor-mounting substrates 10′.

Second Embodiment

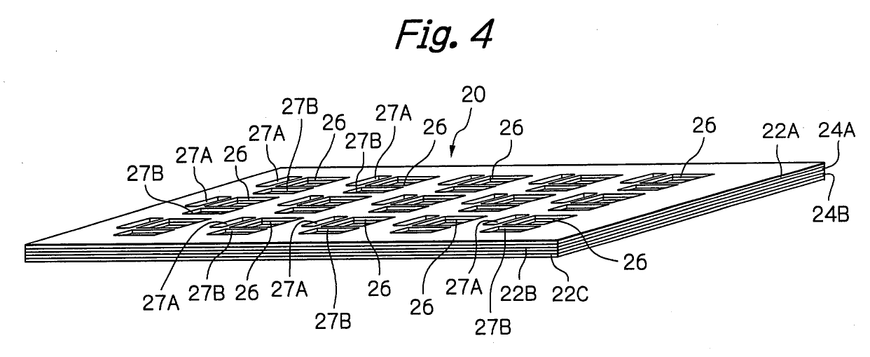

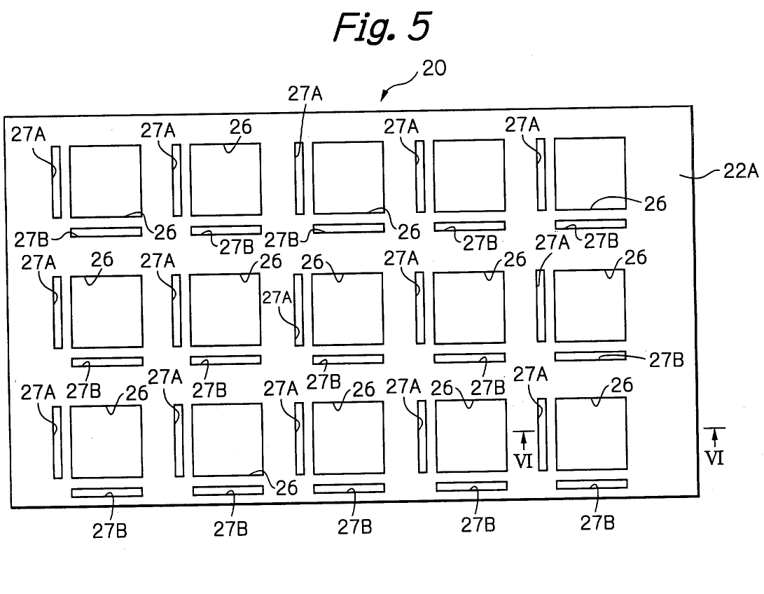

With reference to FIGS. 4 and 5, a second embodiment of the semiconductor-mounting substrate according to the present invention is illustrated in respective perspective and plane views, which embodiment is also used to manufacture a plurality of electronic packages, such as BGA (ball grid array) packages.

As shown in FIG. 4, the semiconductor-mounting substrate, generally indicated by reference 20, is also formed as a multi-layer substrate. Similar to the aforesaid first embodiment, the semiconductor-mounting substrate or multi-layer substrate 20 includes three metal film layers 22A, 22B, and 22C, and two electric insulation layers 24A and 24B, which are alternately laminated. Namely, the metal film layers 22A and 22C form the outermost layers of the multi-layer substrate 20, and the metal film layer 22B forms an intermediate layer, with the respective electric insulation layers 24A and 24B being intervened between the outermost metal film layer 22A and the intermediate metal film layer 22B and between the intermediate metal film layer 22B and the outermost metal film layer 22C.

Note, the respective outermost metal film layers 22A and 22C are referred to as the uppermost metal film layer and the lowermost metal film layer hereinafter.

A plurality of rectangular package areas are defined on the surface of the uppermost metal film layer 22A, and a rectangular recess or opening 26 is formed at each package area in both the uppermost metal film layer 22A and the electric insulation layer 24A, such that the intermediate metal film layer 22B is exposed to the outside at each rectangular opening 26. The exposed rectangular areas of the intermediate metal film layer 22B are used to mount semiconductor chips or bare chips. Namely, each of the rectangular openings 26 serves as a chip-mounting opening.

Also, in the second embodiment, a pair of additional slot-shaped recesses or openings 27A and 27B is formed at each package area in both the uppermost metal film layer 22A and the electric insulation layer 24A such that the slot-shaped openings 27A and 27B are arranged in the vicinity of adjacent two sides of each chip-mounting opening 26, as shown in FIGS. 4 and 5. Note, the function of the slot-shaped openings 27A and 27B will be explained in detail hereinafter.

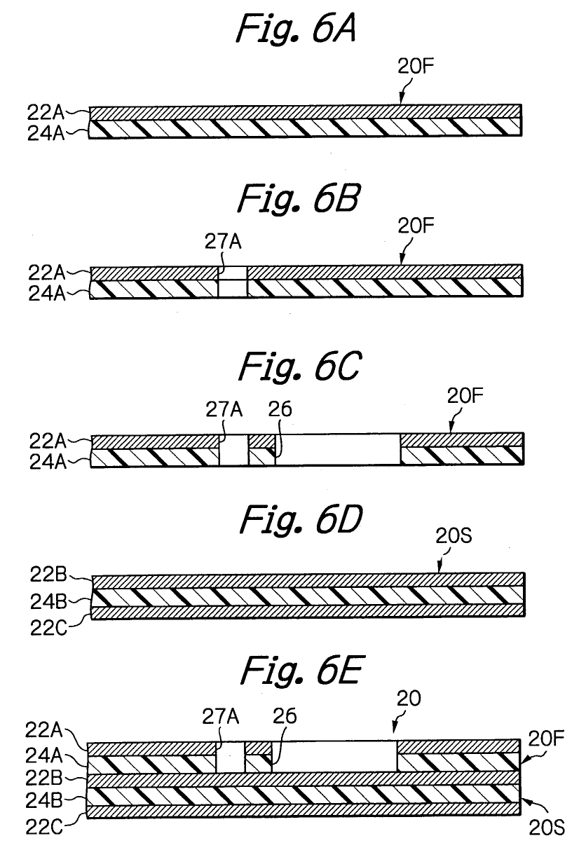

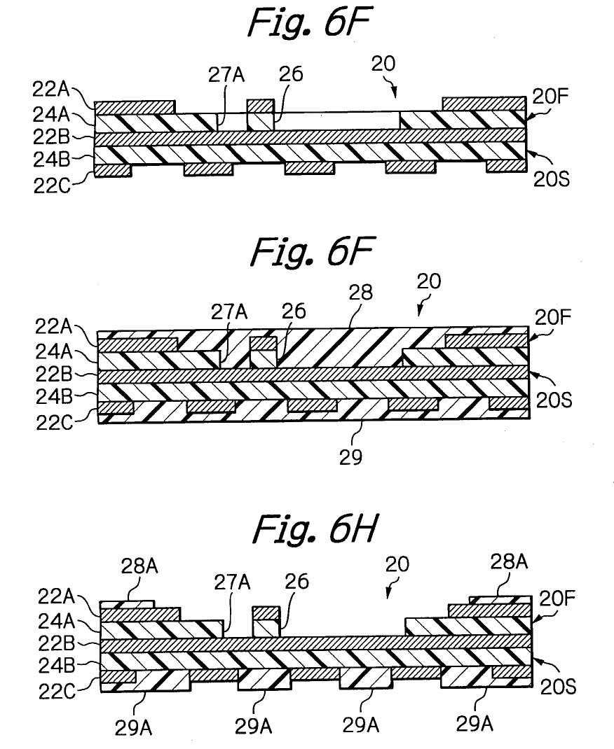

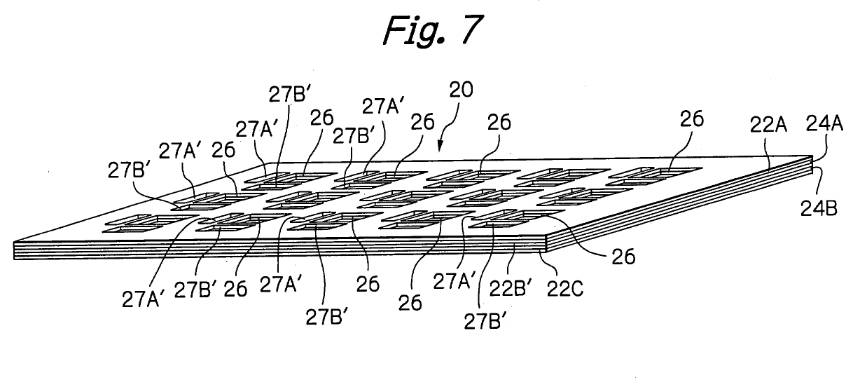

FIGS. 6A to 6E show representative steps forming a production process for producing the semiconductor-mounting substrate or multi-layer substrate 20 shown in FIGS. 4 and 5.

First, as shown in FIG. 6A, a first multi-layer substrate section 20F is prepared, and is composed of the uppermost metal film layer 22A and the electric insulation layer 24A. Similar to the aforesaid first embodiment, the uppermost metal film layer 22A is made from a copper film, and the electric insulation layer 24A is made from a prepreg sheet composed of a glass fiber fabric impregnated with epoxy. Namely, the copper film 22A is laid on the prepreg sheet 24A in which the contained epoxy is in a semi-cured state, and then both the copper film 22A and the prepreg sheet 24A are pressed against each other by a suitable press machine (not shown), resulting in the production of the first multi-layer substrate section 20F.

As shown in FIG. 6B, all the slot-shaped openings 27A and 27B are formed at the respective package areas in the first multi-layer substrate section 20F by a suitable punching press machine (not shown). Note, in FIG. 6B, only one slot-shaped opening 27A is representatively illustrated. It is possible to efficiently carry out the formation of the slot-shaped openings 27A and 27B at once in a stack of first multi-layer substrate sections 20F, using the punching press machine. Namely, it is possible to achieve the formation processing of the slot-shaped openings 27A and 27B at low cost.

Then, as shown in FIG. 6C, all the chip-mounting openings 26 are formed at the respective package areas in the first multi-layer substrate section 20F by a suitable punching press machine (not shown). Note, in FIG. 6C, only one chip-mounting opening 26 is representatively illustrated. It is possible to efficiently carry out the formation of the chip-mounting openings 26 at once in a stack of first multi-layer substrate sections 20F, using the punching press machine. Namely, it is possible to achieve the formation processing of the chip-mounting openings 26 at low cost.

Note, when there is a punching press machine which is capable of simultaneously forming the chip-mounting openings 26 and the slot-shaped openings 27A and 27B in the first multi-layer substrate section 20F, the formation of the chip-mounting openings 26 and the slot-shaped openings 27A and 27B may be carried out at once in the first multi-layer substrate section 20F.

As shown in FIG. 6D, a second multi-layer substrate section 20S is prepared, and is composed of the intermediate and lowermost metal film layers 22B and 22C, and the electric insulation layer 24B. Similar to the first embodiment, each of the metal film layers 22B and 22C is made from a copper film, and the electric insulation layer 24B is made from a prepreg sheet composed of a glass fiber fabric impregnated with epoxy. Namely, the-prepreg sheet 24B, in which the contained epoxy is in a semi-cured state, is sandwiched between the copper films 22B and 22C, and then these elements 22B, 22C, and 24B are pressed against each other by a suitable press machine (not shown), resulting in the production of the second multi-layer substrate section 20S.

Thereafter, the first multi-layer substrate section 20F is laminated onto the second multi-layer substrate section 20S such that the electric insulation layer 24A of the first multi-layer substrate section 20F is laid on the intermediate metal film layer 22B of the second multi-layer substrate section 20S. Then, the laminated first and second multi-layer substrate sections 20F and 20S are pressed against each other by a suitable press machine (not shown), resulting in the production of the semiconductor-mounting substrate 20, as shown in FIG. 6E. Although the first and second multi-layer substrate sections 20F and 20S can be securely adhered to each other, due to the epoxy contained in the prepreg sheet 24A being in the semi-cured state, a suitable adhesive agent may be applied to the surface of the electric insulation layer 24A of the first multi-layer substrate section 20F, if necessary. Note, FIG. 6E corresponds to a partial cross-sectional view of the semiconductor-mounting substrate 20, taken along the VI-VI line of FIG. 5.

While the laminated first and second multi-layer substrate sections 20F and 20S are pressed against each other by the press machine, a part of the electric insulation layer 24A may be squeezed and protruded from inner side wall faces defining each chip-mounting opening 26. Nevertheless, in this second embodiment, it is possible to prevent the protrusion of the part of the electric insulation layer 24A from the inner side wall faces defining each chip-mounting opening 26, due to the provision of the slot-shaped openings 27A and 27B in the semiconductor-mounting substrate 20. In particular, compression stresses, which are produced in the electric insulation layer 24A by the press machine, are relieved at the locations where the slot-shaped openings 27A and 27B are formed, resulting in the prevention of the protrusion of the part of the electric insulation layer 24A from the inner side wall faces defining each chip-mounting opening 26. Namely, each of the additional openings 27A and 27B serves as a stress-relieving opening.

As stated above, although the semiconductor chips are mounted on respective areas of the intermediate metal film layer 22B, which are exposed by the chip-mounting openings 26, the semiconductor-mounting substrate 20 must be further processed before the mounting of the semiconductor chips can be performed, as shown in FIG. 6F, 6G, and 6H.

In particular, as shown in FIG. 6F, the uppermost and lowermost metal film layers 22A and 22C are patterned by a photolithography process and an etching process. Namely, a wiring pattern is formed at each package area in the uppermost metal film layer 22A, and a plurality of electrode pads are correspondingly formed in the lowermost metal film layer 22C. Also, although not illustrated, through holes and via structures are suitably formed in the semiconductor-mounting substrate 20 at each package area, to thereby establish electrical connections between each wiring pattern and the corresponding electrode pads.

Subsequently, as shown in FIG. 6G, the respective upper and lower surfaces of the semiconductor-mounting substrate 20 are coated with a protective or solder resist material to thereby form solder resist layers 28 and 29 thereon. Namely, the wiring patterns formed in the uppermost metal film layer 22A are covered with the solder resist layer 28, and the electrode pads formed in the lowermost metal film layer 22C are covered with the solder resist layer 29. Note, the solder resist material may be composed of epoxy.

Then, as shown in FIG. 6H, the solder resist layers 28 and 29 are patterned by a photolithography process and an etching process. Namely, partial areas of the solder resist layer 28 are left as protective or solder-resist coating areas 28A on each wiring pattern such that electrode pads included in each wiring pattern are exposed to the outside, and partial areas of the solder resist layer 29 are left as protective or solder-resist coating areas 29A on the electrical insulation layer 24B such that the electrode pads formed in the lowermost metal film layer 22C are exposed to the outside.

Thereafter, a semiconductor chip is mounted on each area of the intermediate metal film layer 22B which is exposed by the corresponding opening 26, and then electrical connections are established between the semiconductor chip and the exposed electrode pads of the corresponding wiring pattern by bonding-wires, using a wire bonding machine (not shown). Then, each of the semiconductor chips is sealed together with the bonding-wires by a molded resin, and metal balls are adhered to the electrode pads formed in the lowermost metal film layer 22C. Thus, a BGA package is produced at each package area on the semiconductor-mounting substrate 20, and the semiconductor-mounting substrate 20 is cut and separated into a plurality of BGA packages.

Note, similar to the aforesaid first embodiment, in this field, the semiconductor-mounting substrate 20 per se, as obtained in steps shown in FIG. 6E, 6F, 2G, or 6H may be commercially distributed and circulated as a component part for manufacturing electronic packages, such as BGA packages or the like.

Third Embodiment

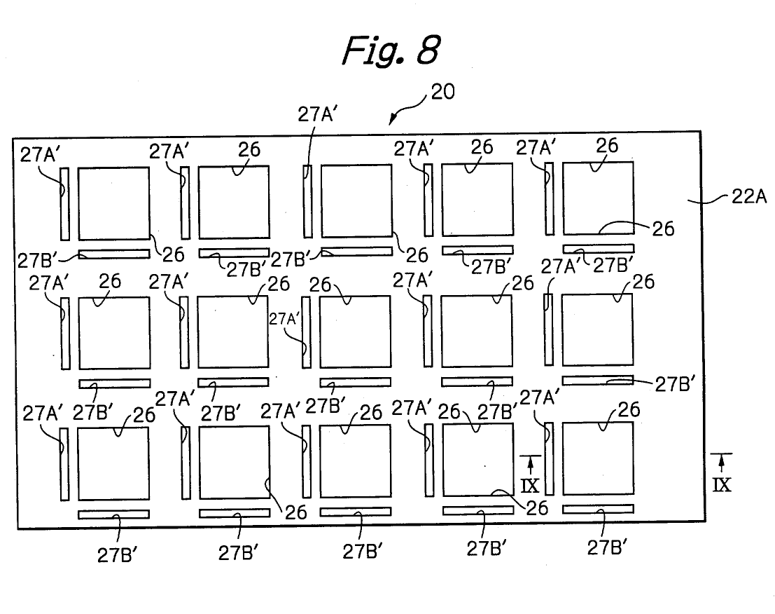

With reference to FIGS. 7 and 8, a third embodiment of the semiconductor-mounting substrate according to the present invention is illustrated in respective perspective and plane views, which embodiment is also used to manufacture a plurality of electronic packages, such as BGA (ball grid array) packages.

As is apparent from FIGS. 7 and 8, a third embodiment of the semiconductor-mounting substrate according to the present invention has an external appearance similar to that of the aforesaid second embodiment shown in FIGS. 4 and 5. Note, in FIGS. 7 and 8, the features similar to those of FIGS. 4 and 5 are indicated by the same references.

Similar to the second embodiment, in the third embodiment, the semiconductor-mounting substrate or multi-layer substrate 20 includes three metal film layers 22A, 22B, and 22C, and two electric insulation layers 24A and 24B, which are alternately laminated. Namely, the respective metal film layers 22A, 22B, and 22C form the uppermost, intermediate, and lowermost metal film layers of the multi-layer substrate 20, with the respective electric insulation layers 24A and 24B being intervened between the uppermost metal film layer 22A and the intermediate metal film layer 22B and between the intermediate metal film layer 22B and the lowermost metal film layer 22C.

Also, similar to the second embodiment, a plurality of rectangular package areas are defined on the surface of the uppermost metal film layer 22A, and a rectangular recess or opening 26 is formed at each package area in both the uppermost metal film layer 22A and the electric insulation layer 24A, such that the intermediate metal film layer 22B is exposed to the outside at each rectangular opening 26. Of course, the respective exposed rectangular areas of the intermediate metal film layer 22B are used to mount semiconductor chips or bare chips. Namely, similar to the aforesaid second embodiment, each of the rectangular openings 26 serves as a chip-mounting opening.

In the third embodiment, a pair of additional slot-shaped recesses or openings 27A′ and 27B′ is formed at each package area in the uppermost metal film layer 22A such that the slot-shaped openings 27A′ and 27B′ are arranged in the vicinity of two adjacent sides of each chip-mounting opening 26, as shown in FIGS. 7 and 8. In short, in the second embodiment, although the slot-shaped openings 27A and 27B are formed at each package area in both the uppermost metal film layer 22A and the electric insulation layer 24A, the slot-shaped openings 27A′ and 27B′ are formed at each package area in only the uppermost metal film layer 22A. In other words, except for this connection, the third embodiment is substantially identical to the aforesaid second embodiment.

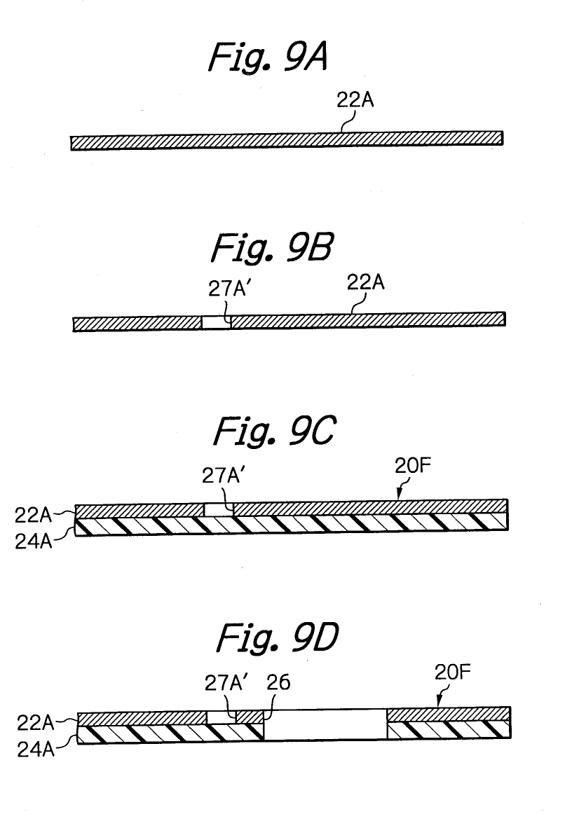

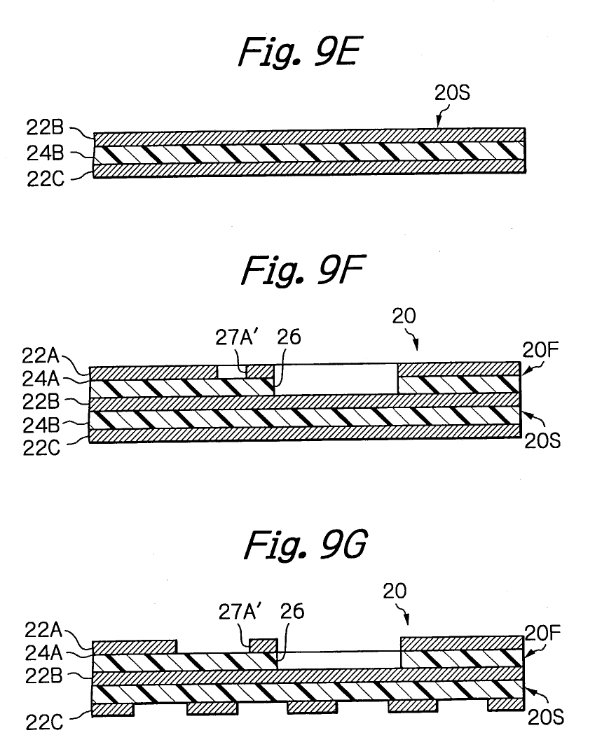

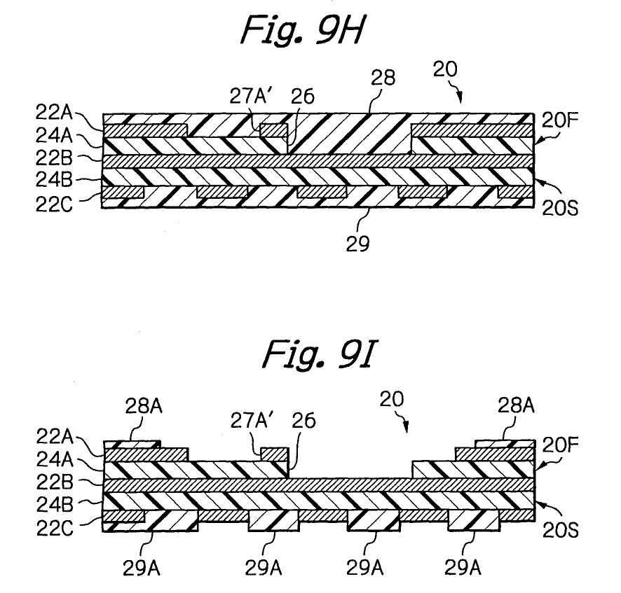

FIGS. 9A to 9F show representative steps forming a production process for producing the semiconductor-mounting substrate or multi-layer substrate 20 shown in FIGS. 7 and 8.

First, as shown in FIG. 9A, a metal film is prepared for the uppermost metal film layer 22A, and a plurality of rectangular package areas are defined on the surface of the metal film 22A. In this third embodiment, the metal film 22A is made of copper.

Then, as shown in FIG. 9B, all the slot-shaped openings 27A′ and 27B′ are formed at the respective package areas in the metal film 22A by a suitable punching machine (not shown). Note, in FIG. 9B, only one slot-shaped opening 27A′ is representatively illustrated. It is possible to efficiently carry out the formation of the slot-shaped openings 27A′ and 27B′ at once in a stack of metal films 22A, using the punching press machine. Namely, it is possible to achieve the formation processing of the slot-shaped openings 27A′ and 27B′ at low cost.

Subsequently, as shown in FIG. 9C, the metal film 22A is laid on an electric insulation sheet or prepreg sheet for the electric insulation layer 24A, and both the metal film 22A and the prepreg sheet 24A are pressed against each other by a suitable press machine (not shown), resulting in a production of a first multi-layer substrate section 20F composed of the metal film or uppermost metal film layer 22A and the prepreg sheet or electric insulation layer 24A. Similar to the first and second embodiment, the prepreg sheet 24A is composed of a glass fiber fabric impregnated with epoxy, and the contained epoxy of the prepreg sheet 24A is in a semi-cured state.

Thereafter, as shown in FIG. 9D, all the chip-mounting openings 26 are formed at the respective package areas in the first multi-layer substrate section 20F by a suitable punching press machine (not shown). Note, in FIG. 9D, only one chip-mounting opening 26 is representatively illustrated. It is possible to efficiently carry out the formation of the chip-mounting openings 26 at once in a stack of first multi-layer substrate sections 20F, using the punching press machine. Namely, it is possible to achieve the formation processing of the chip-mounting openings 26 at low cost.

As shown in FIG. 9E, a second multi-layer substrate section 20S is prepared, and is composed of the intermediate and lowermost metal film layers 22B and 22C, and the electric insulation layer 24B. Similar to the first and second embodiments, each of the metal film layers 22B and 22C is made from a copper film, and the electric insulation layer 24B is made from a prepreg sheet composed of a glass fiber fabric impregnated with epoxy. Namely, the prepreg sheet 24B, in which the contained epoxy is in a semi-cured state, is sandwiched between the copper sheets 22B and 22C, and then these elements 22B, 22C, and 24B are pressed against each other by a suitable press machine (not shown), resulting in the production of the second multi-layer substrate section 20S.

Thereafter, the first multi-layer substrate section 20F is laminated onto the second multi-layer substrate section 20S such that the electric insulation layer 24A of the first multi-layer substrate section 20F is laid on the intermediate metal film layer 22B of the second multi-layer substrate section 20S. Then, the laminated first and second multi-layer substrate sections 20F and 20S are pressed against each other by a suitable press machine (not shown), resulting in the production of the semiconductor-mounting substrate 20, as shown in FIG. 9F. Similar to the above-mentioned embodiments, a suitable adhesive agent may be applied to the surface of the electric insulation layer 24A of the first multi-layer substrate section 20F, if necessary. Note, FIG. 9F corresponds to a partial cross-sectional view of the semiconductor-mounting substrate 20, taken along the IX-IX line of FIG. 8.

While the laminated first and second multi-layer substrate sections 20F and 20S are pressed against each other by the press machine, a part of the electric insulation layer 24A may be squeezed and protruded from inner side wall faces defining each chip-mounting opening 26. Nevertheless, in this third embodiment, it is possible to prevent the protrusion of the part of the electric insulation layer 24A from the inner side wall faces defining each chip-mounting opening 26, due to the provision of the slot-shaped openings 27A′ and 27B′ in the semiconductor-mounting substrate 20. In particular, compression stresses, which are produced in the electric insulation layer 24A by the press machine, are relieved at the locations where the slot-shaped openings 27A′ and 27B′ are formed, resulting in the prevention of the protrusion of the part of the electric insulation layer 24A from the inner side wall faces defining each chip-mounting opening 26. Namely, each of the additional openings 27A′ and 27B′ also serves as a stress-relieving opening.

As stated above, although the semiconductor chips are mounted on respective areas of the intermediate metal film layer 22B, which are exposed by the chip-mounting openings 26, the semiconductor-mounting substrate 20 must be further processed before the mounting of the semiconductor chips can be performed, as shown in FIG. 9G, 9H, and 9I.

In particular, as shown in FIG. 9G, the uppermost and lowermost metal film layers 22A and 22C are patterned by a photolithography process and an etching process. Namely, a wiring pattern is formed at each package area in the uppermost metal film layer 22A, and a plurality of electrode pads are correspondingly formed at each package area in the lowermost metal film layer 22C. Also, although not illustrated, through holes and via structures are suitably formed in the semiconductor-mounting substrate 20 at each package area, to thereby establish electrical connections between each wiring pattern and the corresponding electrode pads.

Subsequently, as shown in FIG. 9H, the respective upper and lower surfaces of the semiconductor-mounting substrate 20 are coated with a protective or solder resist material to thereby form solder resist layers 28 and 29 thereon. Namely, the wiring patterns formed in the uppermost metal film layer 22A are covered with the solder resist layer 28, and the electrode pads formed in the lowermost metal film layer 22C are covered with the solder resist layer 29. Note, the solder resist material may be composed of epoxy.

Then, as shown in FIG. 91, the solder resist layers 28 and 29 are patterned by a photolithography process and an etching process. Namely, partial areas of the solder resist layer 28 are left as protective or solder-resist to coating areas 28A on each wiring pattern such that electrode pads included in each wiring pattern are exposed to the outside, and partial areas of the solder resist layer 29 are left as protective or solder-resist coating areas 29A on the electrical insulation layer 24B such that the electrode pads formed in the lowermost metal film layer 22C are exposed to the outside.

Thereafter, a semiconductor chip is mounted on each area of the intermediate metal film layer 22B which is exposed by the corresponding opening 26, and then electrical connections are established between the semiconductor chip and the exposed electrode pads of the corresponding wiring pattern by bonding-wires, using a wire bonding machine (not shown). Then, each of the semiconductor chips is sealed together with the bonding-wires by a molded resin, and metal balls are adhered to the electrode pads formed in the lowermost metal film layer 22C. Thus, a BGA package is produced at each package area on the semiconductor-mounting substrate 20, and the semiconductor-mounting substrate 20 is cut and separated into a plurality of BGA packages.

Note, similar to the aforesaid first and second embodiments, in this field, the semiconductor-mounting substrate 20 per se, as obtained in steps shown in FIG. 9F, 9G, 9H, or 9I may be commercially distributed and circulated as a component, part for manufacturing electronic packages, such as BGA packages or the like.

Modifications

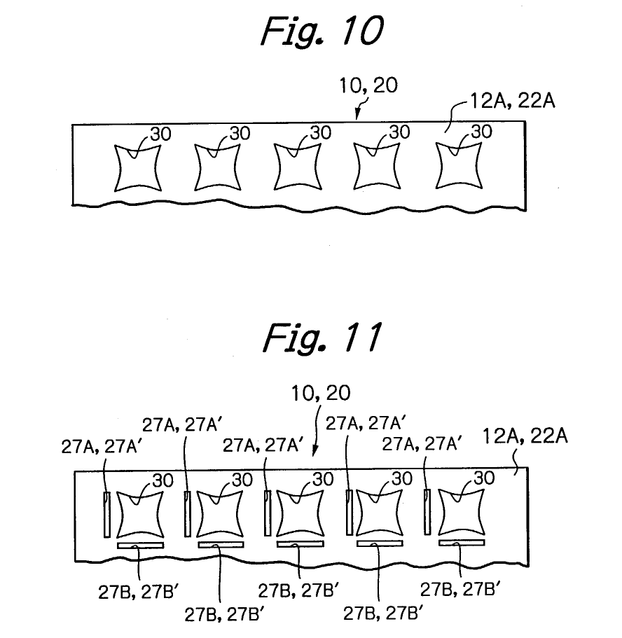

In the above-mentioned embodiments, although the chip-mounting openings (16; 26) have the rectangular shape, they may be shaped into another shape. For example, as shown in FIG. 10, a generally star-shaped opening 30 may be formed at each package area in both the uppermost metal film layer (12A; 22A) and the electric insulation layer (14A; 24A). Namely, each of the inner side wall faces defining the generally star-shaped opening 30 is convexly curved, and the convex shape of each inner side wall face functions to suppress the protrusion of the part of the electric insulation layer (14A; 24A) therefrom, during the pressing of the laminated first and second multi-layer substrate sections (10F and 10S; 20F and 20S) by the press machine.

As shown in FIG. 11, a pair of stress-relieving openings (27A and 27B; 27A′ and 27B′) may be associated with each of the generally star-shaped openings 30. Of course, as already stated, the stress-relieving openings 27A and 27B are formed at each package area in both the uppermost metal film layer (12A; 22A) and the electric insulation layer (14A; 24A), and the stress-relieving openings 27A′ and 27B′ are formed at each package area in only the uppermost metal film layer (12A; 22A).

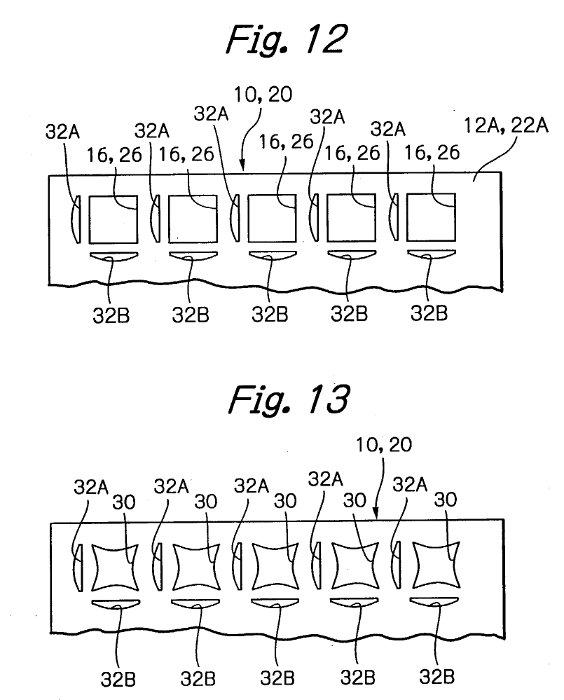

Also, in the above-mentioned embodiments, although the stress-relieving openings (27A and 27B; 27A′ and 27B′) have the slot-like shape, they may be shaped into another shape. For example, as shown in FIG. 12, a pair of generally crescent-shaped openings 32A and 32B may be formed at each package area in either both the uppermost metal film layer (12A; 22A) and the electric insulation layer (14A; 24A) or only the uppermost metal film layer (12A; 22A). Namely, one of side wall faces defining the generally crescent-shaped opening (32A, 32B) is concavely curved, and the concave shape of the side wall face functions to suppress the protrusion of the part of the electric insulation layer (14A; 24A) therefrom, during the pressing of the laminated first and second multi-layer substrate sections (10F and 10S; 20F and 20S) by the press machine. Further, as shown in FIG. 13, the pair of generally crescent-shaped openings 32A and 32B may be associated with each of the generally star-shaped openings 30 shown in FIG. 10.

Although not illustrated, the stress-relieving openings (27A and 27B; 27A′ and 27B′; 32A and 32B) in pair may be connected to and communicated with each other.

Finally, it will be understood by those skilled in the art that the foregoing description is of preferred embodiments of the substrates and processes, and that various changes and modifications may be made to the present invention without departing from the spirit and scope thereof.

1. A semiconductor-mounting substrate used to manufacture a plurality of electronic packages, which substrate comprises:
a first multi-layer substrate section composed of a metal film layer and an electronic insulation layer, a plurality of package areas being defined on a surface of said first multi-layer substrate section; and
a second multi-layer substrate section composed of at least two metal film layers which are spaced from an electric insulation layer intervened therebetween,
wherein said first multi-layer substrate section is laminated onto said second multi-layer substrate section, using a press machine, such that the electronic insulation layer of said first multi-layer substrate section is laid on one of the metal film layers of said second multi-layer substrate section,
wherein a chip-mounting opening is formed at each package area in said first multi-layer substrate section prior to the lamination of said first multi-layer substrate section onto said second multi-layer substrate section.

2. A semiconductor-mounting substrate as set forth in claim 1, wherein the metal film layer of said first multi-layer substrate section is defined as an uppermost metal film layer of the semiconductor-mounting substrate, and another one of the metal film layers of said second multi-layer substrate section is defined as a lowermost metal film layer of the semiconductor-mounting substrate.

3. A semiconductor-mounting substrate as set forth in claim 2, wherein the uppermost and lowermost metal film layers of the semiconductor-mounting substrate are patterned such that a wiring pattern is formed at each package area in said uppermost metal layer, and such that a plurality of electrode pads are correspondingly formed in said lowermost metal film layer.

4. A semiconductor-mounting substrate as set forth in claim 3, wherein the respective outermost surfaces of said semiconductor-mounting substrate are coated with a protective material such that protective layers are formed thereon.

5. A semiconductor-mounting substrate as set forth in claim 4, wherein the respective protective layers of the semiconductor-mounting substrate are patterned such that partial areas of the protective layers are left as protective or solder-resist coating areas on the respective surfaces of the semiconductor-mounting substrate.

6. A semiconductor-mounting substrate as set forth in claim 1, wherein each of said chip-mounting openings is formed as a rectangular opening.

7. A semiconductor-mounting substrate as set forth in claim 1, wherein each of said chip-mounting openings is formed as a generally star-shaped opening, and each of inner side wall faces defining the generally star-shaped opening is convexly curved.

8. A semiconductor-mounting substrate as set forth in claim 1, wherein at least one stress-relieving opening is formed at each package area in said first multi-layer substrate section in the vicinity of the corresponding chip-mounting opening.

9. A semiconductor-mounting substrate as set forth in claim 8, wherein each of said stress-relieving openings is formed as a slot-shaped opening.

10. A semiconductor-mounting substrate as set forth in claim 8, wherein each of said stress-relieving openings is formed as a generally crescent-shaped opening, and at least one of side wall faces defining the generally crescent-shaped opening is concavely curved.

11. A semiconductor-mounting substrate as set forth in claim 1, wherein at least one stress-relieving opening is formed at each package area in the metal film layer of said first multi-layer substrate section in the vicinity of the corresponding chip-mounting opening.

12. A semiconductor-mounting substrate as set forth in claim 11, wherein each of said stress-relieving openings is formed as a slot-shaped opening.

13. A semiconductor-mounting substrate as set forth in claim 11, wherein each of said stress-relieving openings is formed as a generally crescent-shaped opening, and at least one of side wall faces defining the generally crescent-shaped opening is concavely curved.

14. A production process for producing a semiconductor-mounting substrate used to manufacture a plurality of electronic packages, which process comprises:
preparing a first multi-layer substrate section composed of a metal film layer and an electronic insulation layer, a plurality of package areas being defined on a surface of said first multi-layer substrate section;
forming a chip-mounting opening at each package area in said first multi-layer substrate section;
preparing a second multi-layer substrate section composed of at least two metal film layers which are spaced from an electric insulation layer intervened therebetween; and
laminating said first multi-layer substrate section onto said second multi-layer substrate section, using a press machine, such that the electronic insulation layer of said first multi-layer substrate section is laid on one of the metal film layers of said second multi-layer substrate section, resulting in a production of the semiconductor-mounting substrate.

15. A production process as set forth in claim 14, wherein the metal film layer of said first multi-layer substrate section is defined as an uppermost metal film layer of the semiconductor-mounting substrate, and another one of the metal film layers of said second multi-layer substrate section is defined as a lowermost metal film layer of the semiconductor-mounting substrate.

16. A production process as set forth in claim 15, further comprising patterning the uppermost and lowermost metal film layers of said semiconductor-mounting substrate such that a wiring pattern is formed at each package area in said uppermost metal layer, and such that a plurality of electrode pads are correspondingly formed in said lowermost metal film layer.

17. A production process as set forth in claim 16, further comprising coating the respective outermost surfaces of said semiconductor-mounting substrate with a protective material to form protective layers thereon.

18. A production process as set forth in claim 17, further comprising patterning the respective protective layers of said semiconductor-mounting substrate such that partial areas of the protective layers are left as protective or solder-resist coating areas on the respective surfaces of said semiconductor-mounting substrate.

19. A production process as set forth in claim 14, wherein the formation of said chip-mounting openings in said first multi-layer substrate section is carried out, using a punching machine.

20. A production process as set forth in claim 14, wherein the formation of said chip-mounting openings in a stack of first multi-layer substrate sections is carried out at once, using a punching machine.

21. A production process as set forth in claim 14, wherein each of said chip-mounting openings is formed as a rectangular opening.

22. A production process as set forth in claim 14, wherein each of said chip-mounting openings is formed as a generally star-shaped opening, and each of inner side wall faces defining the generally star-shaped opening is convexly curved.

23. A production process as set forth in claim 14, further comprising forming at least one stress-relieving opening at each package area in said first multi-layer substrate section in the vicinity of the corresponding chip-mounting opening.

24. A production process as set forth in claim 23, wherein the formation of said stress-relieving openings in said first multi-layer substrate section is carried out using a punching machine.

25. A production process as set forth in claim 23, wherein the formation of said stress-relieving openings in a stack of first multi-layer substrate sections is carried out at once using a punching machine.

26. A production process as set forth in claim 23, wherein each of said stress-relieving openings is formed as a slot-shaped opening.

27. A production process as set forth in claim 23, wherein each of said stress-relieving openings is formed as a generally crescent-shaped opening, and at least one of side wall faces defining the generally crescent-shaped opening is concavely curved.

28. A production process for producing a semiconductor-mounting substrate used to manufacture a plurality of electronic packages, which process comprises:
preparing a metal film, a plurality of package areas being defined on a surface of said metal film;
forming at least one stress-relieving opening at each package area in said metal film;
laminating said metal film onto an electric insulation sheet to thereby produce a first multi-layer substrate section composed of a metal film layer and an electronic insulation layer derived from said metal film and said electric insulation sheet, respectively;
forming a chip-mounting opening at each package area in said first multi-layer substrate section in the vicinity of the corresponding stress-relieving opening;
preparing a second multi-layer substrate section composed of at least two metal film layers which are spaced from an electric insulation layer intervened therebetween; and
laminating said first multi-layer substrate section onto said second multi-layer substrate section using a press machine, such that the electronic insulation layer of said first multi-layer substrate section is laid on one of the metal film layers of said second multi-layer substrate section, resulting in a production of the semiconductor-mounting substrate.

29. A production process as set forth in claim 28, wherein the metal film layer of said first multi-layer substrate section is defined as an uppermost metal film layer of the semiconductor-mounting substrate, and another one of the metal film layers of said second multi-layer substrate section is defined as a lowermost metal film layer of the semiconductor-mounting substrate.

30. A production process as set forth in claim 29, further comprising patterning the uppermost and lowermost metal film layers of said semiconductor-mounting substrate such that a wiring pattern is formed at each package area in said uppermost metal layer, and such that a plurality of electrode pads are correspondingly formed in said lowermost metal film layer.

31. A production process as set forth in claim 30, further comprising coating the respective outermost surfaces of said semiconductor-mounting substrate with a protective material to form protective layers thereon.

32. A production process as set forth in claim 31, further comprising patterning the respective protective layers of said semiconductor-mounting substrate such that partial areas of the protective layers are left as protective or solder-resist coating areas on the respective surfaces of said semiconductor-mounting substrate.

33. A production process as set forth in claim 28, wherein the formation of said stress-relieving openings in said metal film is carried out using a punching machine.

34. A production process as set forth in claim 28, wherein the formation of said stress-relieving openings in a stack of metal films is carried out at once using a punching machine.

35. A production process as set forth in claim 28, wherein each of said stress-relieving openings is formed as a slot-shaped opening.

36. A production process as set forth in claim 28, wherein each of said stress-relieving openings is formed as a generally crescent-shaped opening, and at least one of side wall faces defining the generally crescent-shaped opening is concavely curved.

37. A production process as set forth in claim 28, wherein the formation of said chip-mounting openings in said first multi-layer substrate section is carried out using a punching machine.

38. A production process as set forth in claim 28, where in the formation of said chip-mounting openings in a stack of first multi-layer substrate sections is carried out at once using a punching machine.

39. A production process as set forth in claim 28, wherein each of said chip-mounting openings is formed as a rectangular opening.

40. A production process as set forth in claim 28, wherein each of said openings is formed as a generally star-shaped opening, and each of inner side wall faces defining the generally star-shaped opening is convexly curved.
